(19) United States
(12) Patent Application Publication
(10) Pub. No.: US 2013/0269756 A1
(43) Pub. Date: Oct. 17, 2013

(54) Tall Slate BITERS

(71) Applicant: Frank Pao, Boston, MA (US)

(72) Inventor: Frank Pao, Boston, MA (US)

(21) Appl. No.: 13/916,095

(22) Filed: Jun. 12, 2013

Related U.S. Application Data
(63) Continuation-in-part of application No. 13/420,484, filed on Mar. 14, 2012.

(51) Int. Cl. H01L 31/048; H01L 31/058; F24J 2/24; F24J 2/04

(52) U.S. Cl. CPC H01L 31/0483; F24J 2/0455; H01L 31/058; F24J 2/24
USPC 136/248; 52/741.1; 126/622; 126/646

(57) ABSTRACT

A roofing installation system for optimally capturing solar thermal energy comprises a plurality of metal battens mounted horizontally onto a plurality of horizontal wooden battens, a plurality of slate modules mounted on the plurality of metal battens and connected in series to form a string, an inverter connected to each string, a thermal tubing containing liquid mounted on the plurality of metal battens, a heat exchanger connected to the thermal tubing, a heat pump connected to the thermal tubing and a circulation pump connected between the thermal tubing and the heat exchanger. The plurality of slate modules generates DC electricity from solar energy and the inverter converts the DC electricity to AC electricity to feed to a utility grid. The plurality of metal battens transfers thermal energy by running liquid in the thermal tubing which is extracted by the heat exchanger thereby producing domestic hot water.

### CROSS-REFERENCE TO RELATED APPLICATIONS

Not Applicable.

### STATEMENT REGARDING FEDERALLY SPONSORED RESEARCH AND DEVELOPMENT

Not Applicable.

### FIELD OF THE DISCLOSURE

This invention relates to a roofing installation system, and more particularly to a roofing installation system for optimally capturing solar thermal energy for producing electrical and thermal energy.

### DISCUSSION OF RELATED ART

Solar cells are well known in the art for producing electrical energy from solar energy and are in wide spread use. The photovoltaic cells have been used for conversion of solar energy directly to electricity. Solar panels are also known to have a hydraulic circuit arranged below the photovoltaic cell and in thermal contact therewith. Such circuits are used to make a part of the solar energy absorbed for various other uses like domestic hot water supply and heating of indoor spaces. Conventional solar panels have low energy conversion efficiency. Conventional flat panel solar panels are expensive, primarily because they contain a large number of silicon solar cells. Because of their low efficiency and corresponding need for increased power, conventional solar panels are typically large and heavy. This reduces their mounting options, or increases the expense and flexibility of mounting. This leaves the user limited in ability to use an optimum number of solar cells. A properly sized and installed solar thermal energy collection system can be a practical alternative for acquiring some of the energy needs. These solar panels comprise of photovoltaic cells arranged on a flat grid.

For example, U. S. Pat. No. 5,293,447 issued to Fanney on Mar. 8, 1994 discloses photovoltaic solar water heating system. A system for heating water using solar energy comprises a photovoltaic array, a water heater comprising a variable resistive load, and a controller for varying either the load characteristics of the resistive load or the power generating characteristics of the photovoltaic array, or both, to ensure maximum power transfer efficiency. However, this arrangement utilizes the electrical energy produced to heat water and hence cannot fulfill the electrical energy demand.

The sun's energy can be collected in a variety of different ways. One is converting sun's energy into thermal energy to heat things, such as water. U. S. Pat. No. 4,738,247 issued to Moore on Apr. 19, 1988 provides roof installations consisting of an array of interfitting members e.g. tiles, strips, slats or the like which interfit to form a roof covering and a set of heat pipes which run parallel to the plane of the roof. Heat is abstracted from the heat pipes and used directly or indirectly, e.g. via a heat pump apparatus. U. S. patent application No. 20080141999 entitled to Hanken on Jun. 19, 2008 provides a solar heating system for mounting under a roof that includes a panel formed of a sheet material and at least one run of tubing held beneath the panel by a plurality of tubing fasteners. The panel assembly facilitates transfer of the trapped heat from the roof and surrounding air into the fluid circulating through the tubing. Such arrangements will not generate sufficient energy to be self sustaining due to less conversion rate and these are not aesthetically pleasing.

U. S. Pat. No. 5,259,363 issued to Peacock on Nov. 9, 1993 teaches a solar roofing panel system for use in residential and commercial buildings employing conventional metal roofing components. The system collects and supplies thermal energy from the sun to heat the interior thereof and also is capable of providing solar generated electricity for powering the normal complement of household appliances. However the system produces thermal and electrical energy, both thermal energy and electrical energy are not produced simultaneously to work in conjunction as well as compensate with each other.

Therefore, there is a need for a thermal electric roofing installation system that eliminates the problem of degradation of conversion rate when the ambient temperature on the roof goes beyond 85 degree Fahrenheit. Further, such a device would effectively utilize the sun's energy, would be self sustaining, aesthetically pleasing, and economical. Such a needed device would simultaneously generate thermal energy and electricity with increased efficiency reducing weight and bulk, improved performance. The present invention accomplishes these objectives.

### SUMMARY OF THE DISCLOSURE

The present invention is a roofing installation system to generate electricity and to provide domestic hot water supply utilizing solar energy. The roofing installation system comprises a plurality of horizontal wooden battens mounted onto a plurality of vertical wooden battens, which are mounted over a slope roof. A plurality of metal battens is mounted on the plurality of horizontal wooden battens. A plurality of link channel brackets having a plurality of hooks is fastened vertically between a pair of the plurality of metal battens using a latch. A plurality of slate modules is mounted on the plurality of metal battens. Each slate module is made to slide through the plurality of link channel brackets till a bottom portion of the slate module fits into the plurality of hooks. An adjacent pair of slate modules is placed on both the edges of each of the plurality of link channel brackets, leaving a central grooved portion. This central grooved portion may act as a drainage channel for the water falling on the slate modules. Each of the plurality of slate modules is connected in series to form a string. The plurality of metal battens may have ridges provided on the surface. The ridges may engage with a right angled protruded portion at a top end of each of the plurality of plurality of link channel brackets which holds the plurality of link channel brackets in position. Any of the slate modules can be removed by swinging the plurality of hooks towards the centre of the link channel bracket. A flange, which is protruding from the bottom side of the link channel bracket, may act as a location guide when placing the plurality of link channel brackets. The installation procedure of the roofing installation system should start at the bottom of the slope roof.

Each of the plurality of metal battens includes a longitudinal channel. A thermal tubing containing liquid or glycol is mounted on the plurality of metal battens along the longitudinal channels, beneath the plurality of slate modules. A circulation pump is connected to the thermal tubing for circulating the liquid through the thermal tubing. A heat exchanger, housed in a storage tank, is connected to the thermal tubing for extracting the thermal energy from the liquid in the thermal tubing and thereby providing domestic hot water. The present invention further comprises a heat pump utilized to maintain the temperature of the liquid in the storage tank to a certain threshold temperature and an inverter connected to the string for converting DC electricity fed from the plurality of slate modules to AC electricity.

The present invention provides a roofing installation system for supporting solar electric modules with thermal tubing over a slope roof. The plurality of slate modules generates DC electricity as the solar energy hits a surface of the plurality of slate modules. The inverter converts the DC electricity to AC electricity and feeds to a utility grid. The plurality of metal battens transfers thermal energy to the running liquid in the thermal tubing. The thermal energy is extracted by the heat exchanger resulting in heating up the domestic water supply and providing domestic hot water.

Another embodiment of the present invention comprises a thermal system having a plurality of storage tanks This embodiment is preferred in areas where severe climatic changes occur. In this embodiment at least one storage tank is placed between the heat pump and the domestic hot water supply. When the heat energy extracted from the thermal tubing reach saturation level the heat pump transfers the heat energy to the second storage tank. As the second tank reaches the maximum capacity, the heat energy is released thereby providing domestic hot water. However, if more heat is needed, the heat pump provides heat energy to the thermal tubing.

As the thermal energy is extracted by the heat exchanger, the plurality of slate modules is cooled thereby making the plurality of slate modules operate at high efficiency in converting the solar energy to DC electricity. In the preferred embodiment, a thermal system and an electric system operate simultaneously to generate domestic hot water and electricity respectively.

### BRIEF DESCRIPTION OF THE DRAWINGS

FIG. 1 is a layout of a roofing installation system in accordance with the present invention;

FIG. 2 is a block diagram of the roofing installation system in accordance with the preferred embodiment of the present invention;

FIG. 3 is a flow chart for a method of mounting the roofing installation system;

FIG. 4 is a block diagram of an alternate embodiment of the present invention illustrating a thermal system on a large roof;

FIG. 5 is a block diagram of another embodiment of the present invention illustrating a thermal system on a large roof with multiple roof plains; and

FIG. 6 is a block diagram of another embodiment of the present invention illustrating a thermal system mounted on a roof where severe climatic changes occur.

### DETAILED DESCRIPTION OF THE PREFERRED EMBODIMENT

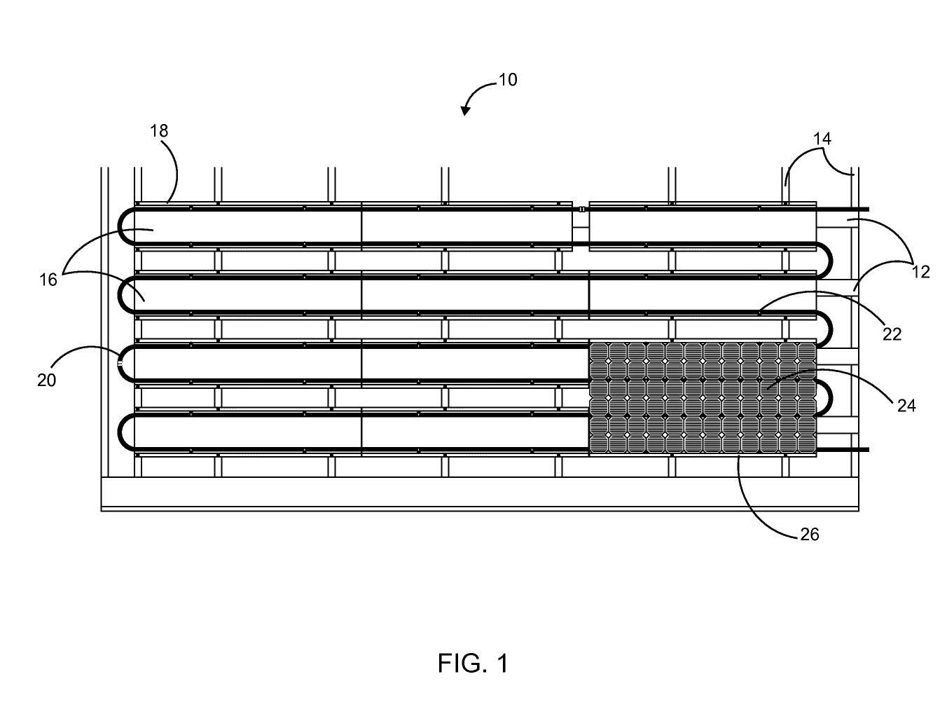

FIG. 1 shows a layout of a roofing installation system 10 for optimally capturing solar thermal energy. The roofing installation system 10 comprises a plurality of horizontal wooden battens 12 mounted onto a plurality of vertical wooden battens 14 that is mounted across a slope roof (not shown). A plurality of metal battens 16 is mounted horizontally onto the plurality of horizontal wooden battens 12. Each of the plurality of metal battens 16 includes a longitudinal channel 18 that extends in a longitudinal direction. A thermal tubing 20 containing liquid is mounted on the plurality of metal battens 16. The thermal tubing 20 extends on the longitudinal channel 18 of each of the plurality of metal battens 16. A plurality of link channel brackets 22 having a hook is fastened vertically between a pair of the plurality of metal battens 16 using a latch. A plurality of slate modules 24 is mounted on the plurality of metal battens 16 by means of the plurality of link channel brackets 22. Each of the plurality of slate modules 24 includes at least one photovoltaic cell. Each of the plurality of slate modules 24 is electrically connected in series to form a string 26. The number of the plurality of slate modules 24 in the string 26 may vary according to the roof design. The plurality of slate modules 24 and the thermal tubing 20 operate simultaneously to generate electricity and domestic hot water respectively.

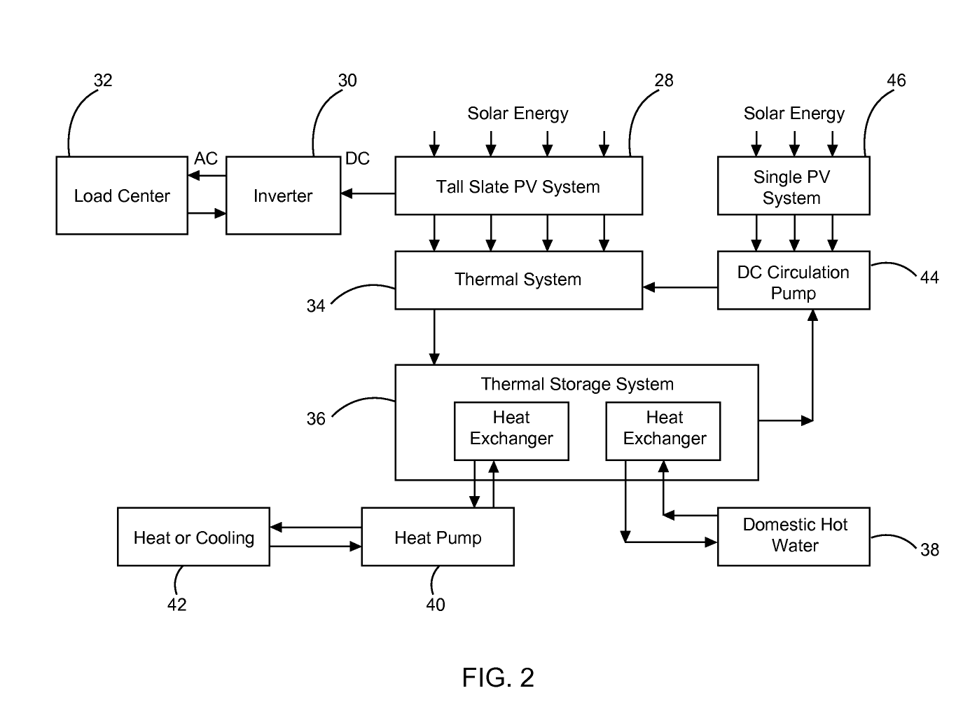

FIG. 2 is a block diagram of the roofing installation system 10 in accordance with the preferred embodiment of the present invention. As the solar energy hits a surface of the plurality of slate modules 24, the plurality of slate modules 24 generates direct current (DC) electricity as indicated at block 28. An inverter converts the DC electricity to alternating current (AC) electricity as indicated at block 30 and feeds to a utility grid as indicated at block 32. The plurality of metal battens 16 converts the solar energy into thermal energy thereby heating up the thermal tubing 20 as indicated at block 34. The thermal tubing 20 extracts the thermal energy down to a heat exchanger housed in a storage tank as indicated at block 36 which results in heating up the domestic water supply thereby providing domestic hot water as indicated at block 38. A heat pump connected to the thermal tubing 20 maintains the temperature to the required level as indicated at block 40 by increasing or decreasing the temperature as indicated at block 42. A circulation pump connected between the thermal tubing 20 and the heat exchanger circulates the liquid through the thermal tubing 20 as indicated at block 44. The circulation pump is powered by a separate photovoltaic module as indicated at block 46.

In the present invention, a thermal system and an electric system work in conjunction as well as compensate with each other. The electric system includes the plurality of slate modules 24 mounted on the roof (not shown). As shown, the plurality of slate modules 24 generates DC electricity as the solar energy hits on the surface of the plurality of slate modules 24 (block 28). The inverter is connected to at least one string 26 of the plurality of slate modules 24. The inverter converts the DC electricity generated by the plurality of slate modules 24 to AC electricity (block 30) and feeds the AC electricity to the utility grid (block 32).

The thermal system includes the thermal tubing 20 connected to the heat exchanger housed in the storage tank (block 36). The circulation pump is connected between the thermal tubing 20 and the heat exchanger for circulating the liquid running through the thermal tubing 20 (block 44). The thermal tubing 20 may be cross-linked polyethylene (PEX), brass, copper, or aluminum tubing and the liquid running through the thermal tubing 20 may be water or glycol. The plurality of metal battens 16 transfers thermal energy through running the liquid in the thermal tubing 20 throughout the roof (not shown). The thermal energy is extracted by the heat exchanger (block 36) resulting in heating up the domestic water supply and providing domestic hot water (block 38). The heat pump is connected to the heat exchanger to maintain the temperature at a certain threshold level (block 40). When the temperature of the liquid in the storage tank is above a certain level, the heat pump reduces the heat to a required level and when the temperature is below a certain level the heat pump provides sufficient heat to maintain the required temperature (block 42). The heat pump is utilized to release the heat in the summer months when more heat is stored in the liquid and to maintain the temperature level when temperature drops below certain level in some winter months.

The separate photovoltaic module for powering the circulation pump (block 46) ensures an independent working of the thermal system in case there are technical problems in the electric system which could prevent the thermal system from operating. Another advantage of using a separate photovoltaic module is that the liquid flowing through the thermal tubing 20 could vary according to the intensity of the solar energy which results in extracting more heat. If more heat is extracted from the roof, the attic cools off thereby generating more domestic hot water and cooling off the plurality of solar electric roof tiles and reduces the air conditioning load.

As the thermal energy is extracted by the heat exchanger, the plurality of slate modules 24 is cooled thereby making the plurality of slate modules 24 operate at high efficiency in converting the solar energy to DC electricity and provides a thermal system that provides sufficient amount of hot water supply for domestic purposes. Thus the thermal system of the present invention eliminates the problem of degradation of conversion rate of solar energy to electric energy when the ambient temperature on the roof (not shown) goes beyond 85 degree Fahrenheit. Moreover, the roofing installation system 10 provides AC electricity thereby reducing heating, ventilation, and air conditioning (HVAC) power consumption. In the preferred embodiment, the thermal system and the electric system operate simultaneously to generate domestic hot water and electricity respectively. With the present system, the roof (not shown) becomes aesthetically pleasing as the thermal part is not exposed to the exterior.

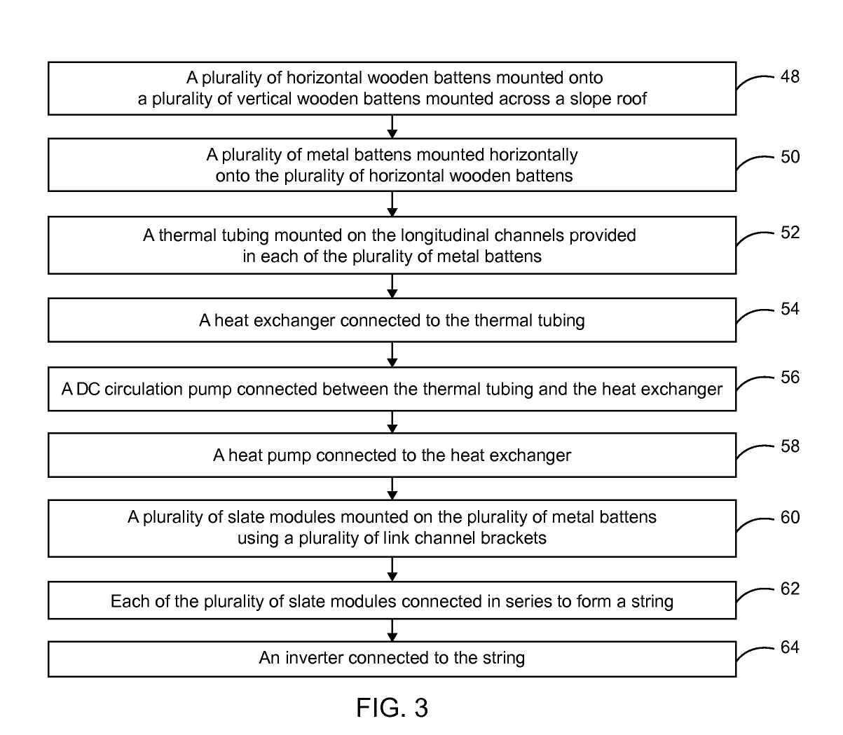

FIG. 3 is a flow chart for a method of mounting the roofing installation system 10. As shown in step 48 a plurality of horizontal wooden battens 12 is mounted onto a plurality of vertical wooden battens 14 mounted across a slope roof. A plurality of metal battens 16 is mounted horizontally onto the plurality of horizontal wooden battens 12 as shown in step 50. A thermal tubing 20 is mounted on the longitudinal channels 18 provided in each of the plurality of metal battens 16 as shown in step 52. A heat exchanger is connected to the thermal tubing 20 as shown in step 54. A circulation pump is connected between the thermal tubing 20 and the heat exchanger as shown in step 56. A heat pump is connected to the heat exchanger as shown in step 58. A plurality of slate modules 24 is mounted on the plurality of metal battens 16 using a plurality of link channel brackets 22 having a hook as shown in step 60. The plurality of link channel brackets 22 is securely fastened between a pair of the plurality of metal battens 16 using a latch. Each of the plurality of slate modules 24 is then slid onto at least one of the plurality of link channel brackets 22 so that a bottom portion of each of the plurality of slate modules 24 fits onto the hook. Each of the plurality of slate modules 24 is connected in series to form a string 26 as shown in step 62. As shown in step 64, an inverter is connected to the string 26 to convert the DC electricity from the plurality of slate modules 24 to AC electricity.

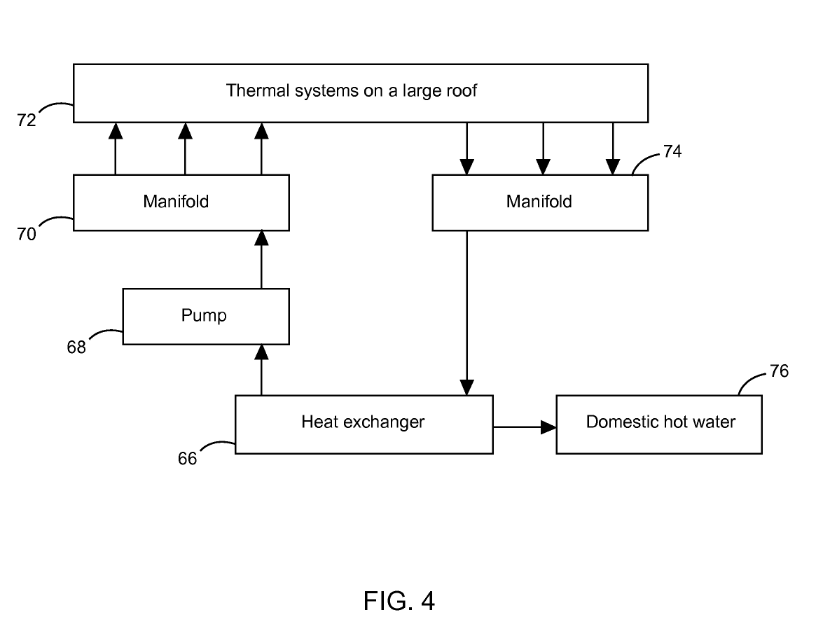

Referring to FIG. 4, a block diagram of an alternate embodiment of the present invention illustrating a thermal system on a large roof that includes a number of loops of the thermal tubing 20 is provided. On large roofs situations, the resistance of the liquid increases as the thermal tubing 20 gets longer which results in building up pressure on flow. A number of loops of the thermal tubing 20 going through the roof reduce the pressure on flow. As shown in the block diagram of the thermal system on a large roof, liquid from the heat exchanger as shown in block 66 is pumped as shown in block 68 through a manifold as shown in block 70 to at least three different loops of the thermal tubing 20 of the thermal system as shown in block 72. The liquid circulating through the loops extracts the thermal solar energy from the roof and then goes through another manifold as shown in block 74 to the heat exchanger as shown in block 66 thereby generating the domestic hot water as shown in block 76.

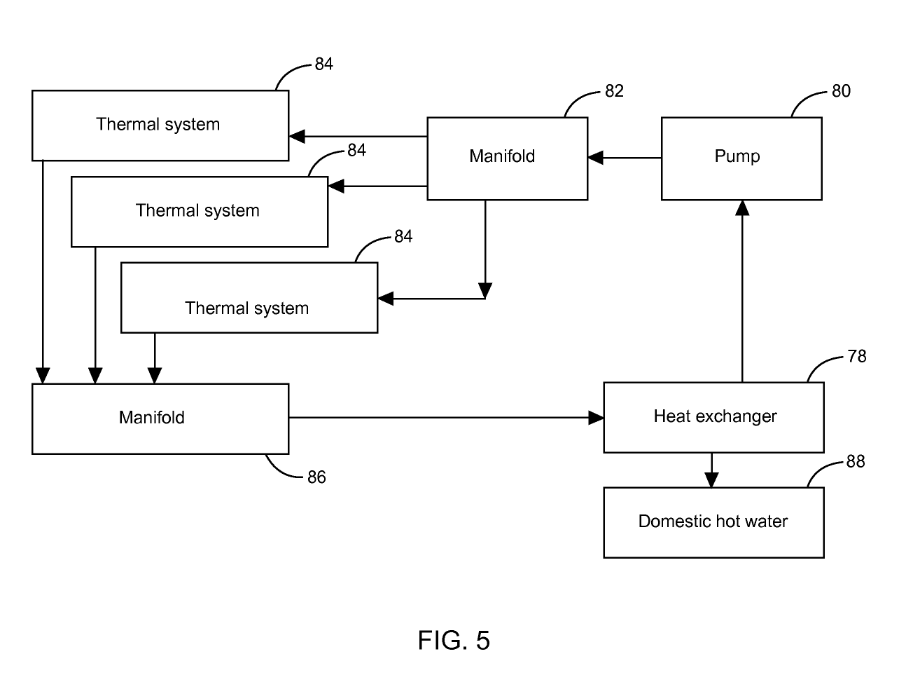

Another embodiment of the invention may include a thermal system on a large roof with multiple roof plains as shown in FIG. 5. In a large house with multiple roof plains, the solar energy intensity varies on each roof plain. Since the variation of the solar energy intensity affects the flow rate and pressure of the liquid in different roof plains, multiple thermal systems are used to accommodate multiple roof plains. The liquid from the heat exchanger as shown in block 78 is pumped as shown in block 80 through a manifold as shown in block 82 to multiple thermal systems as shown in block 84. The liquid circulating through the multiple thermal systems as shown in block 84 extracts the thermal solar energy from the roof and then goes through another manifold as shown in block 86 to the heat exchanger as shown in block 78 thereby generating the domestic hot water as shown in block 88.

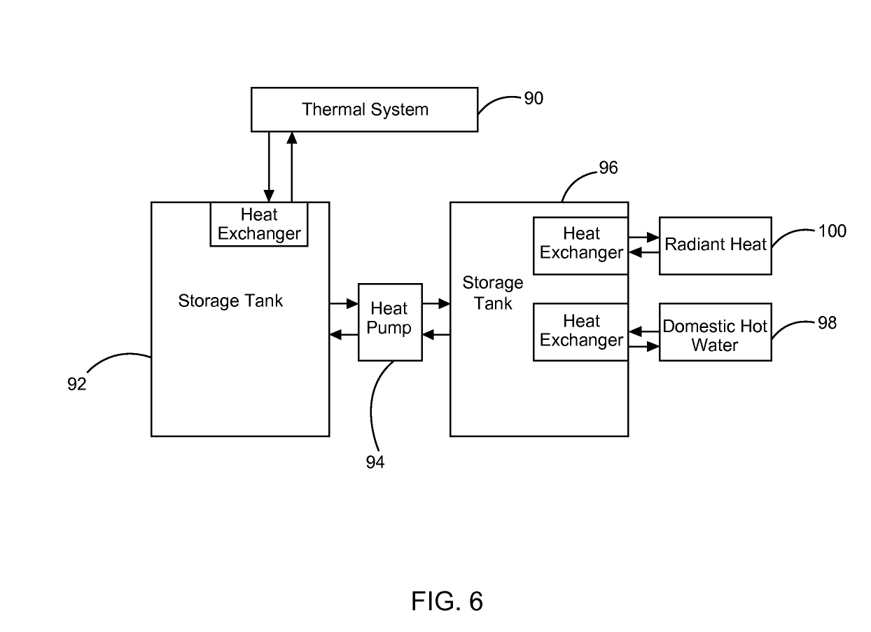

FIG. 6 is a block diagram of another embodiment of the present invention illustrating a thermal system mounted on a roof where severe climatic changes occur. The heat energy of the thermal system 90 is extracted by the heat exchanger housed in the storage tank as shown in block 92. When the heat energy reaches a saturation level the heat pump transfers the heat energy to another storage tank as indicated by block 94. As shown in block 96, the heat exchanger in the second storage tank transfers the heat energy to be used as domestic hot water or as radiant heat as indicated by block 98 and 100.

While a particular form of the invention has been illustrated and described, it will be apparent that various modifications can be made without departing from the spirit and scope of the invention. Accordingly, it is not intended that the invention be limited, except as by the appended claims.

What is claimed is:

1. A roofing installation system for optimally capturing solar thermal energy, the roofing installation system comprising:
a plurality of horizontal wooden battens mounted onto a plurality of vertical wooden battens that being mounted across a slope roof;
a plurality of metal battens mounted horizontally onto the plurality of horizontal wooden battens;
a thermal tubing containing liquid mounted on the plurality of metal battens;
a circulation pump connected to the thermal tubing for circulating the liquid through the thermal tubing;
a heat exchanger connected to the thermal tubing for extracting the thermal energy, the heat exchanger being housed in a storage tank;
a heat pump connected to the heat exchanger for maintaining the temperature of the liquid in the storage tank to a certain threshold temperature;
a plurality of link channel brackets having a hook fastened vertically between a pair of the plurality of metal battens using a latch;
a plurality of slate modules mounted on the plurality of metal battens; and
an inverter for converting DC electricity fed from the plurality of slate modules to AC electricity;
whereby the plurality of slate modules and the thermal tubing operate simultaneously to generate electricity and domestic hot water respectively.

2. The roofing installation system of claim 1 wherein each of the plurality of slate modules includes at least one photovoltaic cell.

3. The roofing installation system of claim 1 wherein each of the plurality of slate modules is electrically connected in series to form a string.

4. The roofing installation system of claim 3 wherein the string is connected to at least one inverter that converts DC electricity fed from the plurality of slate modules to AC electricity and feeds to a utility grid.

5. The roofing installation system of claim 1 wherein the plurality of metal battens collects the solar energy, converts into thermal energy and delivers to the liquid running in the thermal tubing.

6. The roofing installation system of claim 1 wherein the circulation pump is powered by a separate photovoltaic panel.

7. The roofing installation system of claim 1 wherein the heat exchanger extracts the thermal energy from the liquid in the thermal tubing resulting in heating up the domestic water supply and providing domestic hot water.

8. The roofing installation system of claim 1 wherein the thermal tubing may be made of material selected from a group consisting of: copper, aluminum or cross-linked polyethylene (PEX).

9. The roofing installation system of claim 1 wherein the liquid in the thermal tubing may be selected from a group consisting of: water and glycol.

10. The roofing installation system of claim 1 wherein the heat pump maintains the temperature of the liquid in the storage tank when the temperature goes below/above a certain level.

11. The roofing installation system of claim 1 wherein the plurality of slate modules is cooled as the thermal energy is extracted by the heat exchanger, thereby making the plurality of slate modules operate at high efficiency in converting the solar energy to DC electricity.

12. A method of installing a roofing installation system comprising:
a. mounting a plurality of horizontal wooden battens onto a plurality of vertical wooden battens that being mounted across a slope roof;
b. mounting a plurality of metal battens horizontally onto the plurality of horizontal wooden battens;
c. mounting a thermal tubing containing liquid on the plurality of metal battens;
d. connecting a heat exchanger, housed in a storage tank, to the thermal tubing for extracting the thermal energy;
e. connecting a circulation pump between the thermal tubing and the heat exchanger for circulating the liquid running through the thermal tubing;
f. connecting a heat pump to the heat exchanger to maintain the temperature of the liquid in the storage tank to a certain threshold temperature;
g. securely fastening a plurality of link channel brackets having a hook between a pair of the plurality of metal battens using a latch;
h. sliding each of the plurality of slate modules onto at least one of the plurality of link channel brackets so that a bottom portion of each of the plurality of slate modules fits onto the hook;
i. electrically connecting each of the plurality of slate modules in series to form a string; and
j. connecting an inverter to each string for converting the DC electricity from the plurality of slate modules to AC electricity.

13. The method of claim 12 wherein each of the plurality of slate modules includes at least one photovoltaic cell.

14. The method of claim 12 wherein the method of installing the roofing installation system is initiated at the bottom of the slope roof.

15. The method of claim 12 wherein the plurality of metal battens collects the solar energy and converts into thermal energy by running the liquid in the thermal tubing throughout the roof.

16. The method of claim 15 wherein the thermal energy is extracted by the heat exchanger resulting in heating up the domestic water supply and providing domestic hot water.

17. The method of claim 16 wherein the plurality of slate modules is cooled as the thermal energy is extracted by the heat exchanger, thereby making the plurality of slate modules operate at high efficiency in converting the solar energy to DC electricity.

18. The method of claim 12 wherein the heat pump maintains the temperature of the liquid in the storage tank when the temperature goes below/above a certain level.
